(19) United States
(12) Patent Application Publication
(10) Pub. No.: US 2026/0085427 A1
(43) Pub. Date: Mar. 26, 2026

(54) METHOD FOR PRODUCING CERAMIC/METAL BONDED OBJECT

(71) Applicants: OSAKA UNIVERSITY, Osaka (JP); DOWA HOLDINGS CO., LTD., Tokyo (JP)

(72) Inventors: Yuji SATO, Osaka (JP); Keisuke TAKENAKA, Osaka (JP); Kazuki MAKINOSHIMA, Osaka (JP); Masahiro TSUKAMOTO, Osaka (JP); Koji KOBAYASHI, Tokyo (JP); Hideyo OSANAI, Tokyo (JP)

(73) Assignees: OSAKA UNIVERSITY, Osaka (JP); DOWA HOLDINGS CO., LTD., Tokyo (JP)

(21) Appl. No.: 19/109,630

(22) PCT Filed: Oct. 6, 2023
(86) PCT No.: PCT/JP2023/036573

§ 371 Date: Mar. 7, 2025

(30) Foreign Application Priority Data
Oct. 20, 2022 (JP) 2022-168200

(51) Int. Cl. C23C 24/10

(52) U.S. Cl. CPC C23C 24/106; H10W 70/02

(57) ABSTRACT

[Problem] To directly bond a metal layer in a thin line shape to a surface of a ceramic substrate.

[Solution] A method for producing a ceramic-metal bonded object including irradiating a surface of a ceramic substrate with a laser beam while sweeping the laser beam, and simultaneously therewith, feeding a solid metal material toward a region irradiated with the laser beam on the surface of the ceramic substrate (hereinafter referred to as “irradiation area”), so that the metal material being fed is also brought into a state of being irradiated with the laser beam to melt the metal material while heating the surface of the ceramic substrate located in the irradiation area, and depositing the molten metal material on the surface of the ceramic substrate and then solidifying the metal material.

### TECHNICAL FIELD

The present invention relates to a method for producing a ceramic-metal bonded object in which a metal material melted by a laser beam is directly bonded to the surface of a ceramic substrate.

### BACKGROUND ART

A ceramic-metal bonded object, that is, a composite material in which a ceramic and a metal are integrated through the bonding portions of the two is, for example, useful in applications such as an insulated circuit board for mounting a semiconductor element. In general, in the production of an insulated circuit board, a method in which a copper-based or aluminum-based metal sheet member is bonded to the surface of a ceramic substrate, and thereafter an unnecessary part of the metal sheet member is removed by etching to form a circuit pattern is adopted. In this case, the step of forming the circuit pattern requires a procedure involving the formation of a resist film, etching processing, and removal of the resist film, resulting in increased production load and cost.

The “molten metal bonding method” is known as a method for directly forming a metal layer with a layout corresponding to a specified circuit pattern on the surface of a ceramic plate. The molten metal bonding method is a method in which a molten metal is solidified on the surface of a ceramic plate placed in a mold, and the layout of the metal layer to be bonded to the surface of the ceramic plate can be set based on the void pattern in the mold. However, it is difficult to form a metal layer in a thin line shape using the molten metal bonding method. Although the molten metal bonding method can be applied to an aluminum-based metal, it is not industrially easy to apply the method to a copper-based metal having a high melting point.

A thermal spraying technique is known as a method for directly bonding a copper-based metal to the surface of a ceramic. For example, PTL 1 shows an example in which a copper layer with a thickness of 75 μm (Example 1) or 30 μm (Example 2) was formed on the surface of a roughened aluminum oxide plate by a plasma spraying method in which a copper powder is supplied into a hot gas flow produced by a plasma burner. PTL 2 shows examples (Examples 1, 6, and 7) in which a conductive film with a thickness of 50 μm to 1.5 mm was formed by spraying a metal such as aluminum, nickel, copper, or stainless steel onto the surface of a ceramic substrate of aluminum nitride or the like using a thermal spraying method such as arc spraying, plasma spraying, or flame spraying. However, it is difficult to form a metal layer in a thin line shape using a thermal spraying method.

“Brazing” is a method for surface bonding a ceramic plate and a metal material. In brazing, a brazing material is applied to the bonding interface between the materials to be bonded. Typical examples of the brazing material include a silver paste and an Ag—Cu-based alloy sheet. The use of such a brazing material requires a step such as applying a paste of the brazing material to the bonding surfaces of materials to be bonded, or preparing a brazing material sheet in a specified shape and placing it at a specified position between materials to be bonded prior to brazing. If a “brazing material integrated ceramic plate”, in which a specified amount of a brazing material is selectively bonded to a portion to become a bonding surface of a ceramic plate, can be prepared in advance, this can contribute to reduction in the load of the brazing step. It is not easy to form a thin brazing material layer made of a small amount of a silver-based metal at a specified position on a ceramic plate using a thermal spraying method.

Meanwhile, “laser metal deposition” is known as a method for coating the surface of a metal substrate with a different type of metal. This is a technique in which a laser beam is used to melt a metal powder, which is a coating material, near the surface of a metal substrate, and the molten metal is deposited on the metal substrate. For example, PTL 3 discloses a powder overlaying apparatus that uses multiple laser beams simultaneously.

PTL 4 discloses a coating method in which a copper overlay layer is formed on the surface of stainless steel, which is a substrate, by supplying a copper powder, which is a coating material, into a laser beam. Specifically, an example, in which a mixed powder made of two types of pure copper with different particle diameters was used, the spot diameter of a blue laser was set to about 0.5 mm, and an overlay layer in a straight line shape was formed on the surface of SUS 304, which is an object (substrate), at a scanning speed of 4 mm/s by changing the laser output in the range of 20 to 80 W, is shown (paragraphs 0054 to 0057).

### CITATION LIST

### Patent Literature

PTL 1: JPH07-501855A
PTL 2: JP2006-89290A
PTL 3: WO2017/170890
PTL 4: JP2022-13563A

### SUMMARY OF INVENTION

### Technical Problem

According to the laser metal deposition technique, it is possible to form a pure copper overlay layer in a thin line shape with a line width of, for example, about 0.5 mm on the surface of a metal substrate as shown in the example in PTL 4. However, bonding a layer of any of various metals including copper-based and silver-based metals in a thin line shape to the surface of a ceramic substrate is more difficult than when the substrate is a metal, and the technique has not been established.

An object of the invention is to provide a ceramic-metal bonded object using a technique capable of directly bonding a metal layer in a thin line shape to the surface of a ceramic substrate.

### Solution to Problem

As a result of studies, the inventors found that it is possible to realize bonding of a ceramic and a metal using a laser metal deposition technique by bringing the surface of a ceramic substrate into a state of being sufficiently heated using a laser beam. When the substrate is a metal, as taught in PTL 4, by setting conditions such that a sprayed coating material metal (welding material) is preferentially melted and melting of the metal substrate (object) is minimized, the molten coating material metal (welding material) adheres to the surface of the metal substrate (object) and is then naturally cooled and solidified, and the surface of the metal substrate (object) can be coated with an overlay layer made of a metal film without involving a molten pool (paragraph 0034 in PTL 4). That is, the molten metal relatively easily adheres to the surface of a different type of metal in a solid state. However, when the substrate is a ceramic, it is difficult to bond the ceramic to a solidified material of a coating material metal under laser irradiation conditions such that the coating material metal is simply melted directly above the ceramic substrate. In order to obtain a ceramic-metal bonded object using the laser metal deposition method, it is important to sufficiently heat the surface of a ceramic which is a substrate and to deposit the molten material of a coating material metal that is supplied sequentially onto the surface of the ceramic. The invention has been made based on this finding. Specifically, the following inventions are disclosed in this description.

[1] A method for producing a ceramic-metal bonded object including irradiating a surface of a ceramic substrate with a laser beam while sweeping the laser beam, and simultaneously therewith, feeding a solid metal material toward a region irradiated with the laser beam on the surface of the ceramic substrate (hereinafter referred to as “irradiation area”), so that the metal material being fed is also brought into a state of being irradiated with the laser beam to melt the metal material while heating the surface of the ceramic substrate located in the irradiation area, and depositing the molten metal material on the surface of the ceramic substrate and then solidifying the metal material.

[2] The method for producing a ceramic-metal bonded object according to the above [1], in which the solid metal material is a powder.

[3] The method for producing a ceramic-metal bonded object according to the above [1] or [2], in which the solid metal material contains any of Cu, Ag, Ti, Ni, Al, Fe, Au, and Pt as a main component.

[4] The method for producing a ceramic-metal bonded object according to the above [1] or [2], in which the solid metal material contains Cu or Ag as a main component.

[5] The method for producing a ceramic ceramic-metal bonded object metal bonded object according to any one of the above [1] to [4], in which one or more laser beams are used, and at least one of the laser beams to be emitted to the metal material being fed has a wavelength of 600 nm or less.

[6] The method for producing a ceramic-metal bonded object according to any one of the above [1] to [4], in which one or more laser beams are used, and for at least one of the laser beams to be emitted to the metal material being fed, any of a Yb-doped solid-state laser, a Nd-doped solid-state laser, a GaN semiconductor laser, a copper vapor laser, an Ar gas laser, a N₂ gas laser, and an excimer laser is used as a light source.

[7] The method for producing a ceramic ceramic-metal bonded object metal bonded object according to any one of the above [1] to [6], in which the solid metal material contains Cu as a main component, and the ceramic substrate contains AlN as a main component.

[8] The method for producing a ceramic-metal bonded object according to the above [7], in which one or more laser beams are used, and the surface of the ceramic substrate is irradiated with the laser beam so that an average irradiation energy density E represented by formula (1) below is 80 to 160 J/mm²:

$$E = ( {P}_{L 1} / {D}_{L 1} + {P}_{L 2} / {D}_{L 2} + … + {P}_{L n} / {D}_{L n} ) / v \qquad ( 1 )$$

in which
E: an average irradiation energy density E (J/mm²),
sign Li (i=an integer of 1 or more and n or less, n being a total number of laser beams used): an identification sign of each laser beam used,
P_{Li}: a laser output (W) of a laser beam Li,
D_{Li}: an irradiation spot diameter (mm) in a direction perpendicular to a sweep direction of the laser beam Li, and
v: a sweep speed (mm/s) of a laser beam.

[9] The method for producing a ceramic ceramic-metal bonded object metal bonded object according to any one of the above [1] to [6], in which the solid metal material contains Ag as a main component, and the ceramic substrate contains AlN or Si₃N₄ as a main component.

The method for producing a ceramic-metal bonded object according to the above [9], in which one or more laser beams are used, and the surface of the ceramic substrate is irradiated with the laser beam so that an average irradiation energy density E represented by formula (1) below is 25 to 160 J/mm²:

$$E = ( {P}_{L 1} / {D}_{L 1} + {P}_{L 2} / {D}_{L 2} + … + {P}_{L n} / {D}_{L n} ) / v \qquad ( 1 )$$

in which
E: an average irradiation energy density E (J/mm²), sign Li (i=an integer of 1 or more and n or less, n being a total number of laser beams used): an identification sign of each laser beam used,
P_{Li}: a laser output (W) of a laser beam Li,
D_{Li}: an irradiation spot diameter (mm) in a direction perpendicular to a sweep direction of the laser beam Li, and
v: a sweep speed (mm/s) of a laser beam.

In the present description, the “irradiation spot” means a region on the surface of a ceramic substrate that is irradiated by the path of a certain one laser beam. At least one of the laser beams used need to hit a metal material being fed. As for the laser beam that hits the metal material being fed, a region on the surface of a ceramic substrate to be irradiated when it is assumed that the laser beam reaches the surface of a ceramic substrate without being blocked by the metal material being fed in the middle of the path is defined as the “irradiation spot” of the laser beam. The “irradiation area” means a region that belongs to any one of the irradiation spots and is formed of a position on the surface of a ceramic substrate. When only one laser beam is used, the “irradiation area” and the “irradiation spot” necessarily coincide. When multiple laser beams are used, the range of each “irradiation spot” coincides with or is smaller than the range of the “irradiation area”, but when all the irradiation spots by each laser beam coincide, the “irradiation area” and each “irradiation spot” coincide.

The “main component” means a component whose content in mass ratio is 50% or more among the components forming the material. For example, “a solid metal material containing Cu as a main component” means a solid metal material having a Cu content of 50 mass % or more. The “ceramic substrate containing AlN as a main component” means a ceramic substrate having an AlN content of 50 mass % or more. In the present description, among the metal materials, a metal material containing Cu as a main component is called “copper-based” and a metal material containing Ag as a main component is called “silver-based”.

### Advantageous Effects of Invention

According to the invention, it has become possible to obtain a “ceramic-metal bonded object” in which a metal layer is formed directly on the surface of a ceramic substrate by a laser metal deposition method. The metal layer can be formed into a thin line shape with a width of, for example, 0.5 mm or less, and therefore the invention can be used as a method for directly forming a copper-based metal circuit pattern on an insulating substrate for mounting a semiconductor element. It can also be used as a method for producing a “brazing material integrated ceramic plate” in which a silver-based brazing material is selectively bonded to a specified position.

### BRIEF DESCRIPTION OF DRAWINGS

FIG. 1 is a diagram schematically illustrating the configuration of a laser metal deposition apparatus that can be used in the invention.

FIG. 2 shows an example of a height profile measured in the width direction by a laser microscope for a line-shaped metal layer obtained in Example 1.

FIG. 3 shows an example of a height profile measured in the width direction by a laser microscope for a line-shaped metal layer obtained in Example 2.

FIG. 4 shows an example of a height profile measured in the width direction by a laser microscope for a line-shaped metal layer obtained in Example 3.

FIG. 5 shows an example of a height profile measured in the width direction by a laser microscope for a line-shaped metal layer obtained in Example 4.

FIG. 6 shows an example of a height profile measured in the width direction by a laser microscope for a line-shaped metal layer obtained in Example 5.

FIG. 7 is a photograph illustrating the appearance of a ceramic plate after a metal layer production test of each example was performed.

### DESCRIPTION OF EMBODIMENTS

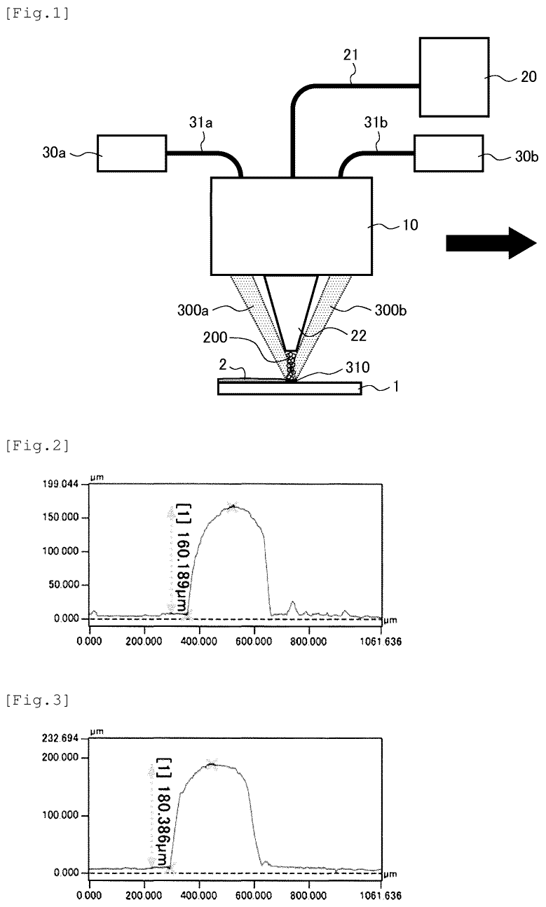

FIG. 1 schematically illustrates the configuration of a laser metal deposition apparatus that can be used in the invention. Here, a typical configuration of a two-beam emission type is shown as an example, but it is also possible to adopt an apparatus of a type that emits only one beam or of a type that emits three or more beams. A processing head 10 is a unit that has a means for spraying a metal powder which is a coating material in a specified direction and a means for emitting a laser beam in a specified direction, and is capable of moving horizontally above a ceramic substrate 1 while maintaining a specified distance from the surface of the ceramic substrate 1. The metal powder which is a coating material is guided from a powder supply device 20 to the processing head 10 through a powder supply pipe 21, and is discharged from a powder feed nozzle 22 attached to the processing head 10 toward the surface of the ceramic substrate 1. The flying metal powder discharged from the powder feed nozzle 22 is denoted by reference numeral 200 in the drawing. Meanwhile, the laser light generated by laser generators 30a and 30b is guided to the processing head 10 through optical fibers 31a and 31b, respectively, and laser beams 300a and 300b are emitted in a specified direction from a lens (not shown) built in the processing head 10. In the example in FIG. 1, the discharge of the metal powder and the emission of the laser beam are performed while the processing head 10 is moved in the direction of the arrow.

The laser beams 300a and 300b are emitted onto the metal powder 200 being flying to heat the metal powder 200 in a solid state, and are also emitted onto the surface of the ceramic substrate 1 to heat an irradiation area 310, which is a region on the surface of the ceramic substrate 1 that is irradiated with the laser beams. Most of the particles of the metal powder 200 are melted while flying, but it does not matter in a case where particles that are melted at the time point when they reach the irradiation area 310 are contained. In other words, the solid metal material which is a coating material is melted during feeding while being irradiated with the laser beam, or when it reaches the surface of the ceramic substrate. Note that the particle size of the metal powder 200 in the drawing is drawn in an exaggerated manner.

The obtained molten metal is deposited on the surface of the ceramic substrate 1 while keeping the molten state because the irradiation area 310 is sufficiently heated. In other words, it is important that the molten metal is not solidified and exploded immediately after it reaches the ceramic substrate 1, but remains in a molten state on the surface of the ceramic substrate 1 although in a short time. During that short time, the surface of the ceramic substrate 1 remains wet with the molten metal. The molten metal deposited on the ceramic substrate 1 is solidified after the irradiation area 310, which is swept as the processing head 10 moves, leaves, and a metal layer 2 is formed in a line shape in the region where the irradiation area 310 has passed on the surface of the ceramic substrate 1. This metal layer 2 is firmly bonded to the ceramic substrate 1 during the solidification process. In this manner, a “ceramic-metal bonded object” in which the metal layer 2 is bonded onto the surface of the ceramic substrate 1 is constructed. When the sweep of the irradiation area 310 is scanned in the direction perpendicular to the sweep path on the ceramic substrate 1, the metal layer 2 in a planar shape can also be formed.

A space where the molten metal is generated between the processing head 10 and the ceramic substrate 1, and the surface including the irradiation area 310 of the ceramic substrate 1 are preferably shielded with an inert gas such as Ar to prevent oxidation of the metal. Although a gas shielding mechanism is not shown in FIG. 1, it is possible to adopt, for example, a mechanism in which a sleeve surrounding each laser beam and the powder feed nozzle 22 is provided at the lower part of the processing head 10 so that the lower end thereof does not come into contact with the ceramic substrate 1, a shielding gas is supplied from the processing head 10 into the sleeve, and the shielding gas discharged from the lower end of the sleeve is sprayed onto a surface region including the irradiation area 310 of the ceramic substrate 1.

In FIG. 1, an example in which the irradiation area 310 is formed by a common irradiation spot created by the two laser beams 300a and 300b is shown, but as another irradiation method, for example, a method in which the focus of some laser beams of the multiple laser beams is adjusted to a position where the powder being flying is easy to melt, and the focus of the other laser beams is adjusted so that the surface of the ceramic substrate 1 is heated most efficiently may be adopted. Further, in the example in FIG. 1, a method for spraying a metal powder from the powder feed nozzle 22 as a method for feeding a solid metal which is a coating material is shown, but it is also possible to adopt a method for feeding, for example, a wire material in place of the powder.

### [Solid Metal Material]

As the solid metal material of the raw material used as the coating material, one containing, as a main component, an element such as Cu, Ag, Ti, Ni, Al, Fe, Au, or Pt can be used. A method for directly bonding a metal containing such an element as a main component in a thin line shape to a ceramic substrate has not been established so far. In particular, a copper-based metal is widely used as a metal for a circuit of an insulated circuit board, and a silver-based metal is widely used as a brazing material, and therefore, in the case of applying the material to such uses, a material containing Cu or Ag as a main component may be used.

More specifically, it is preferred to use pure copper with a Cu content of 99.9 mass % or more as the copper-based metal for a circuit.

As the silver-based metal for a brazing material, one having an Ag—Cu-based near-eutectic composition is preferred. It is more preferred to contain 0.5 to 5 mass % Ti as an active metal. For example, a brazing material of an Ag—Cu—Ti alloy containing Cu: 23 to 33 mass % and Ti: 0.5 to 5 mass %, with the balance being Ag can be exemplified. In addition, various Ag brazing materials specified in JIS Z 3261:1998 can be applied.

When a metal powder is used as the solid metal material, a powder with a cumulative 50% particle diameter D50 in the volume-based particle size distribution measured by a laser diffraction/scattering method of, for example, 5 to 100 μm can be used, and a powder with a D50 in the range of 10 to 30 μm is more preferred. A mixed powder in which two or more types of metal powders are mixed in a specified ratio may also be used.

### [Ceramic Substrate]

As the ceramic substrate, those made of various materials are applicable. Examples thereof include one containing aluminum nitride (AlN) as a main component, one containing silicon nitride (Si₃N₄) as a main component, and one containing aluminum oxide (Al₂O₃) as a main component. When an insulated circuit board is constructed, a ceramic plate with a thickness of, for example, about 0.25 to 1.0 mm may be used.

### [Laser]

In the invention, solid metal materials of various metals including copper-based and silver-based metals are melted by the energy of a laser beam. When a metal material containing Cu is applied, it is effective to use a laser with a wavelength of 600 nm or less. When multiple laser beams are used, it is desirable to use a laser with a wavelength of 600 nm or less as at least one of the laser beams. Typical examples of the laser with a wavelength of 600 nm or less include a blue laser with a wavelength of around 450 nm.

### [Average Irradiation Energy Density E]

In the invention, in order to bond a ceramic and a metal, it is important to deposit a molten metal on the surface of a ceramic, that is, to make the surface of a ceramic wet with a molten metal. Since a ceramic is a material which is mainly made of an inorganic compound with a high melting point and has a different nature from a metal, it is difficult to realize bonding between a ceramic substrate and a metal after solidification unless the surface of the ceramic substrate goes through a state of being wet with a molten metal even in a short time. In the case of a thermal spraying method, the amount of a molten metal sprayed onto the surface of a ceramic substrate is large, and the amount of heat applied to the ceramic substrate by plasma or the like is also large, so that the wetting of the ceramic and the molten metal is easily ensured. On the other hand, when a small amount of a metal sufficient for forming a metal layer in a thin line shape with a width of, for example, 0.5 mm or less is melted by the energy of a laser, there is a problem that the molten metal is easily solidified immediately after it reaches the surface of the ceramic substrate. As a result of the study, it was verified that a molten metal can be deposited on the surface of a ceramic by intentionally irradiating the surface of a ceramic substrate with a laser beam and sufficiently heating the irradiation area, so that bonding between the ceramic substrate and the metal layer in a thin line shape can be realized.

The energy of the laser beam applied to the irradiation area on the surface of the ceramic substrate is sufficient when it is strong enough to be able to realize the deposition of the molten metal, but more specifically, when the coating material metal contains Cu as a main component and the ceramic substrate contains AlN as a main component, it is effective to use one or more laser beams and set an average irradiation energy density E represented by the following formula (1) to 80 to 160 J/mm². Further, when the coating material metal contains Ag as a main component and the ceramic substrate contains AlN or Si₃N₄ as a main component, it is effective to use one or more laser beams and set an average irradiation energy density E represented by the following formula (1) to 25 to 160 J/mm².

$$E = ( {P}_{L 1} / {D}_{L 1} + {P}_{L 2} / {D}_{L 2} + … + {P}_{L n} / {D}_{L n} ) / v \qquad ( 1 )$$

Here,
E: an average irradiation energy density E (J/mm²),
sign Li (i=an integer of 1 or more and n or less, n being a total number of laser beams used): an identification sign of each laser beam used,
P_{Li}: a laser output (W) of a laser beam Li,
D_{Li}: an irradiation spot diameter (mm) in a direction perpendicular to a sweep direction of the laser beam Li, and
v: a sweep speed (mm/s) of a laser beam.

When the right side is expanded, the above formula (1) is expressed as the following formula (2).

$$E = {P}_{L 1} / ( {D}_{L 1} \times v ) + {P}_{L 2} / ( {D}_{L 2} \times v ) + … + {P}_{L n} / ( {D}_{L n} \times v ) \qquad ( 2 )$$

Here, taking a case where only one laser beam is used as an example, the above formula (2) is expressed as the following formula (2-1).

$$E = {P}_{L 1} / ( {D}_{L 1} \times v ) \qquad ( 2 - 1 )$$

The numerator P_{Li} is the laser output (W), which corresponds to the energy per second (unit: [J/s]). The denominator D_{Li}×ᵥ is a term that represents the beam sweep area per second (unit: [mm]·[mm/s]=[mm²/s]). When a track through which the center point of the irradiation spot passes on the surface of the ceramic substrate is referred to as “sweep axis”, in a region through which the irradiation spot passes in one second, the closer the position is to the sweep axis, the longer the time it takes for the irradiation spot to pass, so that the energy applied becomes higher. Therefore, it can be considered that E (unit: [J/s]/[mm²/s]=[J/mm²]) represented by the above formula (2-1) is an index that represents the average energy applied per unit area in one second. Accordingly, in the invention, the above E is called an “average irradiation energy density E”. Since the laser beam also hits the coating material metal being fed on the way to the irradiation spot on the surface of the ceramic substrate, a part of the laser output P_{Li} is consumed for heating and melting the coating material metal. The average irradiation energy density E can be regarded as a value obtained by converting the laser output P_{L1} distributed between a portion for irradiating the coating material metal and a portion for directly irradiating the surface of the ceramic substrate into the average energy applied per unit area of the irradiation spot passing region on the surface of the ceramic substrate in one second.

When multiple laser beams are used, the average irradiation energy density E can be regarded as the sum of individual average irradiation energy densities E applied to the irradiation area by the irradiation spot of each laser beam, as represented by the above formula (2).

In order to realize the deposition of a molten metal on the surface of the ceramic substrate, it is advantageous to increase the average irradiation energy density E. According to the study by the inventors, when the coating material metal contains Cu as a main component and the ceramic substrate contains AlN as a main component, it is preferred to use one or more laser beams and set the average irradiation energy density E of the above formula (1) to 80 J/mm² or more, and more preferably 90 J/mm² or more. In addition, when the coating material metal contains Ag as a main component (for example, an Ag—Cu-based brazing material such as an Ag—Cu—Ti alloy), and the ceramic substrate contains AlN or Si₃N₄ as a main component, it is preferred to use one or more laser beams and set the average irradiation energy density E of the above formula (1) to 25 J/mm² or more, and more preferably 40 J/mm² or more. In particular, when the ceramic substrate contains AlN as a main component, it is preferred to set the average irradiation energy density E to 50 J/mm² or more, and more preferably 60 J/mm² or more. On the other hand, when the average irradiation energy density E becomes large, damage to the ceramic substrate is more likely to occur. Regardless of whether the main component of the ceramic substrate is AlN or Si₃N₄, the average irradiation energy density E is preferably set in the range of 160 J/mm² or less, and more preferably set in the range of 120 J/mm² or less. The feed amount per unit time of the metal material needs to be adjusted according to the irradiation conditions of the laser beam so that the metal material to be fed is sufficiently melted.

### EXAMPLES

An attempt was made to bond a metal layer made of a copper-based metal or a silver-based metal in a thin line shape to the surface of a ceramic substrate using a laser metal deposition apparatus of a two-beam emission type having a configuration shown in FIG. 1. The experimental method will be described below.

As the ceramic substrate, a 30 mm square, 1 mm thick aluminum nitride (AlN) plate (manufactured by TD Power Materials Co., Ltd.), and a 30 mm square, 1 mm thick silicon nitride (Si₃N₄) plate (manufactured by MARUWA CO., LTD.) were prepared. As the metal material for the coating material, a copper powder (manufactured by Sanyo Special Steel Co., Ltd.) having a cumulative 50% particle diameter D50 in a volume-based particle size distribution measured by a laser diffraction/scattering method of 29.0 μm and a purity of 99.96% and an Ag—Cu—Ti alloy powder (manufactured by Kojundo Chemical Lab. Co., Ltd.) having a cumulative 50% particle diameter D50 in a volume-based particle size distribution measured by a laser diffraction/scattering method of 24.3 μm and a composition of Ag: 70.92 mass %, Cu: 27.58 mass %, and Ti: 1.50 mass % were prepared.

The aluminum nitride plate or the silicon nitride plate (hereinafter, these may be simply referred to as “ceramic plate”) was fixed on a horizontal board with one surface facing vertically upward, and while moving a processing head (reference numeral 10 in FIG. 1) of a laser metal deposition apparatus at a constant speed in the horizontal direction (in the direction of the arrow in FIG. 1), the copper powder or the Ag—Cu—Ti alloy powder (hereinafter, these may be simply referred to as “metal powder”) was melted as follows. A blue laser was generated by each of two laser generators (reference numerals 30a and 30b in FIG. 1) of the laser metal deposition apparatus, and the two laser beams were emitted onto the surface of a ceramic plate (reference numeral 1 in FIG. 1) from the processing head, and simultaneously therewith, the metal powder housed in a powder supply device (reference numeral 20 in FIG. 1) was discharged from a powder feed nozzle (reference numeral 22 in FIG. 1) by Ar gas. The distance between the discharge port (lower end) of the powder feed nozzle and the surface of the ceramic plate was set to about 5 mm. The two laser beams were emitted so that the respective irradiation spots formed on the surface of the ceramic plate coincided. That is, an irradiation area (reference numeral 310 in FIG. 1) formed by the two laser beams has the same size as each irradiation spot. In addition, the irradiation spot of each laser beam has a circular shape. The metal powder, which is a coating material, was discharged and fed in the direction toward the irradiation area, and at least one beam of the two laser beams hits the metal powder being fed, so that almost all the metal powder being fed was melted by the time it reached the irradiation area. At the lower part of the processing head, a sleeve surrounding each laser beam and the powder feed nozzle was provided so that the lower end thereof was about 5 mm from the surface of the ceramic plate, and Ar gas was constantly supplied from the processing head into the sleeve as a shielding gas during irradiation with the laser beam, and the Ar gas discharged from the lower end of the sleeve was sprayed onto the surface region including the irradiation area of the ceramic plate.

An attempt was made to bond a line-shaped metal layer to the surface of the ceramic plate by sweeping the irradiation area about 20 mm while the metal powder was melted in this manner. The test conditions and results of each example are summarized in Tables 1 and 2. In Tables 1 and 2, the two laser beams are distinguished as Beams 1 and 2, respectively. The above (1) is expressed here as the following formula (1-2).

$$E = ( {P}_{L 1} / {D}_{L 1} + {P}_{L 2} / {D}_{L 2} ) / v \qquad ( 1 - 2 )$$

E: an average irradiation energy density (J/mm²)
P_{Li} and P_{L2}: laser outputs (W) of laser beams 1 and 2, respectively
D_{Li} and D_{L2}: irradiation spot diameters (mm) of laser beams 1 and 2, respectively
v: a sweep speed (mm/s) of a laser beam

Evaluation of the formation of a metal layer was shown based on the following criteria, and one evaluated as A was determined as acceptable.
A: A line-shaped metal layer was bonded to the surface of the ceramic plate.
B: A line-shaped metal solidified material was formed on the surface of the ceramic plate, but did not bond to the ceramic plate.
C: The molten metal was scattered on the surface of the ceramic plate, and a line-shaped metal solidified material was not formed.

### Comparative Example 1

As the ceramic plate, the aluminum nitride plate was used. A blue laser with a wavelength of 450 nm was used for both beams 1 and 2, and the laser output was set to 40 W and the irradiation spot diameter was set to 0.26 mm for both beams. The copper powder was fed at a supply rate of 10 mg/s, and the sweep speed for the irradiation spot was set to 5.0 mm/s. The flow rate of the shielding gas was 10 L/min. The average irradiation energy density E calculated according to the above formula (1-2) was 61.5 J/mm².

Under the conditions, the molten metal was not deposited on the ceramic plate, and a line-shaped metal solidified material was not formed (evaluated as C).

### Comparative Example 2

An attempt was made to form a metal layer under the same conditions as in Comparative Example 1 except that the laser output was set to 45 W for both beams 1 and 2. The average irradiation energy density E was 69.2 J/mm².

Even under the conditions, the molten metal was not deposited on the ceramic plate, and a line-shaped metal solidified material was not formed (evaluated as C).

### Comparative Example 3

An attempt was made to form a metal layer under the same conditions as in Comparative Example 1 except that the laser output was set to 50 W for both beams 1 and 2. The average irradiation energy density E was 76.9 J/mm².

It is thought that the molten metal could not be sufficiently deposited on the ceramic plate under the conditions, and although a line-shaped metal solidified material was formed, it did not bond to the ceramic plate (evaluated as B).

### Example 1

An attempt was made to form a metal layer under the same conditions as in Comparative Example 1 except that the laser output was set to 55 W for both beams 1 and 2. The average irradiation energy density E was 84.6 J/mm².

Under the conditions, the molten metal could be sufficiently deposited on the ceramic plate, and a line-shaped metal layer was bonded to the ceramic plate (evaluated as A).

FIG. 2 shows an example of a height profile measured in the width direction of a line-shaped metal layer by a laser microscope for the line-shaped metal layer bonded onto the ceramic plate obtained in this example. The line width roughly corresponded to the diameter of the irradiation area of the laser beam (=the irradiation spot diameter of the beam 1 or 2), and the thickness (top height) of the metal layer was about 160 μm. It was verified that a metal layer in a thin line shape can be bonded to the surface of a ceramic substrate (the same applies to each of the following Examples).

### Example 2

An attempt was made to form a metal layer under the same conditions as in Comparative Example 1 except that the laser output was set to 60 W for both beams 1 and 2. The average irradiation energy density E was 92.3 J/mm².

Even under the conditions, the molten metal could be sufficiently deposited on the ceramic plate, and a line-shaped metal layer was bonded to the ceramic plate (evaluated as A).

FIG. 3 shows an example of a height profile measured in the width direction of a line-shaped metal layer by a laser microscope for the line-shaped metal layer bonded onto the ceramic plate obtained in this example. The line width roughly corresponded to the diameter of the irradiation area of the laser beam, and the thickness (top height) of the metal layer was about 180 μm.

With respect to a ceramic-metal bonded object in which the line-shaped metal layer was bonded under the same conditions as in this example, the shear strength (bond strength) was examined by the following method.

### (Method for Measuring Shear Strength)

The ceramic-metal bonded object was cut to a width of 10 mm perpendicular to the longitudinal direction of the line-shaped metal layer of the ceramic-metal bonded object to form an evaluation sample. The evaluation sample was attached to a shear tester (model: SPST2000N) manufactured by Adwelds Co., Ltd., and the shear strength was measured by applying an external force in a direction perpendicular to the longitudinal direction of the line-shaped metal layer and parallel to the surface of the ceramic to the line-shaped metal layer at a feed rate of 0.25 mm/sec with a shear tool.

As a result, the shear strength was 26.6 MPa.

### Example 3

An attempt was made to form a metal layer under the same conditions as in Comparative Example 1 except that the laser output was set to 65 W for both beams 1 and 2. The average irradiation energy density E was 100.0 J/mm².

Even under the conditions, the molten metal could be sufficiently deposited on the ceramic plate, and a line-shaped metal layer was bonded to the ceramic plate (evaluated as A). When the shear strength was examined by the above method for a ceramic-metal bonded object in which the line-shaped metal layer was bonded under the same conditions as in this example, the shear strength was 38.1 MPa.

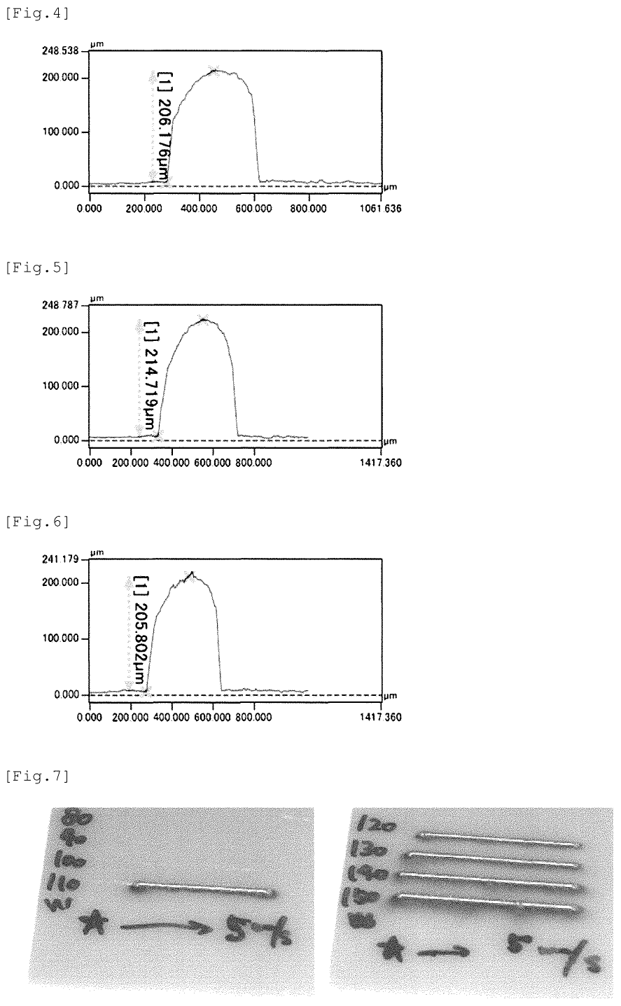

FIG. 4 shows an example of a height profile measured in the width direction of a line-shaped metal layer by a laser microscope for the line-shaped metal layer bonded onto the ceramic plate obtained in this example. The line width roughly corresponded to the diameter of the irradiation area of the laser beam, and the thickness (top height) of the metal layer was about 206 μm.

### Example 4

An attempt was made to form a metal layer under the same conditions as in Comparative Example 1 except that the laser output was set to 70 W for both beams 1 and 2. The average irradiation energy density E was 107.7 J/mm².

Even under the conditions, the molten metal could be sufficiently deposited on the ceramic plate, and a line-shaped metal layer was bonded to the ceramic plate (evaluated as A).

FIG. 5 shows an example of a height profile measured in the width direction of a line-shaped metal layer by a laser microscope for the line-shaped metal layer bonded onto the ceramic plate obtained in this example. The line width roughly corresponded to the diameter of the irradiation area of the laser beam, and the thickness (top height) of the metal layer was about 215 μm.

### Example 5

An attempt was made to form a metal layer under the same conditions as in Comparative Example 1 except that the laser output was set to 75 W for both beams 1 and 2. The average irradiation energy density E was 115.4 J/mm².

Even under the conditions, the molten metal could be sufficiently deposited on the ceramic plate, and a line-shaped metal layer was bonded to the ceramic plate (evaluated as A).

FIG. 6 shows an example of a height profile measured in the width direction of a line-shaped metal layer by a laser microscope for the line-shaped metal layer bonded onto the ceramic plate obtained in this example. The line width roughly corresponded to the diameter of the irradiation area of the laser beam, and the thickness (top height) of the metal layer was about 206 μm.

### Example 6

As the ceramic plate, the silicon nitride plate was used. A blue laser with a wavelength of 450 nm was used for both beams 1 and 2, and the laser output was set to 20 W and the irradiation spot diameter was set to 0.26 mm for both beams. The above-described Ag—Cu—Ti alloy powder was fed at a supply rate of 10 mg/s, and the sweep speed for the irradiation spot was set to 5.0 mm/s. The flow rate of the shielding gas was 10 L/min. The average irradiation energy density E calculated according to the above formula (1-2) was 30.8 J/mm².

Under the conditions, the molten metal could be sufficiently deposited on the ceramic plate, and a line-shaped metal layer was bonded to the ceramic plate (evaluated as A).

According to a height profile measured in the width direction of a line-shaped metal layer by a laser microscope for the line-shaped metal layer bonded onto the ceramic plate obtained in this example, the line width roughly corresponded to the diameter of the irradiation area of the laser beam, and the thickness (top height) of the metal layer was about 94 μm.

### Example 7

An attempt was made to form a metal layer under the same conditions as in Example 6 except that the laser output was set to 25 W for both beams 1 and 2. The average irradiation energy density E was 38.5 J/mm².

Even under the conditions, the molten metal could be sufficiently deposited on the ceramic plate, and a line-shaped metal layer was bonded to the ceramic plate (evaluated as A).

According to a height profile measured in the width direction of a line-shaped metal layer by a laser microscope for the line-shaped metal layer bonded onto the ceramic plate obtained in this example, the line width roughly corresponded to the diameter of the irradiation area of the laser beam, and the thickness (top height) of the metal layer was about 117 μm.

### Example 8

An attempt was made to form a metal layer under the same conditions as in Example 6 except that the Ag—Cu—Ti alloy powder was fed at a supply rate of 5 mg/s. The average irradiation energy density E was 30.8 J/mm².

Even under the conditions, the molten metal could be sufficiently deposited on the ceramic plate, and a line-shaped metal layer was bonded to the ceramic plate (evaluated as A).

According to a height profile measured in the width direction of a line-shaped metal layer by a laser microscope for the line-shaped metal layer bonded onto the ceramic plate obtained in this example, the line width roughly corresponded to the diameter of the irradiation area of the laser beam, and the thickness (top height) of the metal layer was about 83 μm.

### Example 9

An attempt was made to form a metal layer under the same conditions as in Example 6 except that the Ag—Cu—Ti alloy powder was fed at a supply rate of 12.5 mg/s. The average irradiation energy density E was 30.8 J/mm².

Even under the conditions, the molten metal could be sufficiently deposited on the ceramic plate, and a line-shaped metal layer was bonded to the ceramic plate (evaluated as A).

According to a height profile measured in the width direction of a line-shaped metal layer by a laser microscope for the line-shaped metal layer bonded onto the ceramic plate obtained in this example, the line width roughly corresponded to the diameter of the irradiation area of the laser beam, and the thickness (top height) of the metal layer was about 110 μm.

### Example 10

An attempt was made to form a metal layer under the same conditions as in Example 6 except that the Ag—Cu—Ti alloy powder was fed at a supply rate of 15 mg/s. The average irradiation energy density E was 30.8 J/mm².

Even under the conditions, the molten metal could be sufficiently deposited on the ceramic plate, and a line-shaped metal layer was bonded to the ceramic plate (evaluated as A).

According to a height profile measured in the width direction of a line-shaped metal layer by a laser microscope for the line-shaped metal layer bonded onto the ceramic plate obtained in this example, the line width roughly corresponded to the diameter of the irradiation area of the laser beam, and the thickness (top height) of the metal layer was about 107 μm.

### Example 11

An attempt was made to form a metal layer under the same conditions as in Example 6 except that the laser output was set to 40 W for both beams 1 and 2, and the Ag—Cu—Ti alloy powder was fed at a supply rate of 15 mg/s. The average irradiation energy density E was 61.5 J/mm².

Even under the conditions, the molten metal could be sufficiently deposited on the ceramic plate, and a line-shaped metal layer was bonded to the ceramic plate (evaluated as A). When the shear strength was examined in the same manner as in Example 2 for a ceramic-metal bonded object in which the line-shaped metal layer was bonded under the same conditions as in this example, the shear strength was 92.0 MPa or more.

According to a height profile measured in the width direction of a line-shaped metal layer by a laser microscope for the line-shaped metal layer bonded onto the ceramic plate obtained in this example, the line width roughly corresponded to the diameter of the irradiation area of the laser beam, and the thickness (top height) of the metal layer was about 167 μm.

### Example 12

An attempt was made to form a metal layer under the same conditions as in Example 6 except that the laser output was set to 35 W for both beams 1 and 2, and the Ag—Cu—Ti alloy powder was fed at a supply rate of 12.5 mg/s. The average irradiation energy density E was 53.8 J/mm².

Even under the conditions, the molten metal could be sufficiently deposited on the ceramic plate, and a line-shaped metal layer was bonded to the ceramic plate (evaluated as A). When the shear strength was examined in the same manner as in Example 2 for a ceramic-metal bonded object in which the line-shaped metal layer was bonded under the same conditions as in this example, the shear strength was 42.2 MPa or more.

According to a height profile measured in the width direction of a line-shaped metal layer by a laser microscope for the line-shaped metal layer bonded onto the ceramic plate obtained in this example, the line width roughly corresponded to the diameter of the irradiation area of the laser beam, and the thickness (top height) of the metal layer was about 165 μm.

### Example 13

As the ceramic plate, the aluminum nitride plate was used. A blue laser with a wavelength of 450 nm was used for both beams 1 and 2, and the laser output was set to 45 W and the irradiation spot diameter was set to 0.26 mm for both beams. The above-described Ag—Cu—Ti alloy powder was fed at a supply rate of 5 mg/s, and the sweep speed for the irradiation spot was set to 5.0 mm/s. The flow rate of the shielding gas was 10 L/min. The average irradiation energy density E calculated according to the above formula (1-2) was 69.2 J/mm².

Even under the conditions, the molten metal could be sufficiently deposited on the ceramic plate, and a line-shaped metal layer was bonded to the ceramic plate (evaluated as A).

According to a height profile measured in the width direction of a line-shaped metal layer by a laser microscope for the line-shaped metal layer bonded onto the ceramic plate obtained in this example, the line width roughly corresponded to the diameter of the irradiation area of the laser beam, and the thickness (top height) of the metal layer was about 74 μm.

### Example 14

An attempt was made to form a metal layer under the same conditions as in Example 13 except that the laser output was set to 55 W for both beams 1 and 2. The average irradiation energy density E was 84.6 J/mm².

Even under the conditions, the molten metal could be sufficiently deposited on the ceramic plate, and a line-shaped metal layer was bonded to the ceramic plate (evaluated as A).

According to a height profile measured in the width direction of a line-shaped metal layer by a laser microscope for the line-shaped metal layer bonded onto the ceramic plate obtained in this example, the line width roughly corresponded to the diameter of the irradiation area of the laser beam, and the thickness (top height) of the metal layer was about 60 μm.

### Example 15

An attempt was made to form a metal layer under the same conditions as in Example 13 except that the laser output was set to 50 W for both beams 1 and 2, and the Ag—Cu—Ti alloy powder was fed at a supply rate of 10 mg/s. The average irradiation energy density E was 76.9 J/mm².

Even under the conditions, the molten metal could be sufficiently deposited on the ceramic plate, and a line-shaped metal layer was bonded to the ceramic plate (evaluated as A).

According to a height profile measured in the width direction of a line-shaped metal layer by a laser microscope for the line-shaped metal layer bonded onto the ceramic plate obtained in this example, the line width roughly corresponded to the diameter of the irradiation area of the laser beam, and the thickness (top height) of the metal layer was about 64 μm.

### Example 16

An attempt was made to form a metal layer under the same conditions as in Example 13 except that the laser output was set to 55 W for both beams 1 and 2, and the Ag—Cu—Ti alloy powder was fed at a supply rate of 7.5 mg/s. The average irradiation energy density E was 84.6 J/mm².

Even under the conditions, the molten metal could be sufficiently deposited on the ceramic plate, and a line-shaped metal layer was bonded to the ceramic plate (evaluated as A).

According to a height profile measured in the width direction of a line-shaped metal layer by a laser microscope for the line-shaped metal layer bonded onto the ceramic plate obtained in this example, the line width roughly corresponded to the diameter of the irradiation area of the laser beam, and the thickness (top height) of the metal layer was about 73 μm.

TABLE 1

| | | | | Laser beam irradiation conditions | | | |
|---|---|---|---|---|---|---|---|
| | | | | Beam 1 | | | |
| | | | | | | Irradiation | |
| | | Ceramic plate | | | | spot | Beam 2 |
| | Coating | | Thickness | Wavelength | Laser output | diameter | Wavelength |
| Example No. | material metal | Material | (mm) | (nm) | P_{L1} (W) | D_{L1} (mm) | (nm) |
| Comparative example 1 | Copper powder | AlN | 1.0 | 450 | 40 | 0.26 | 450 |
| Comparative example 2 | Copper powder | AlN | 1.0 | 450 | 45 | 0.26 | 450 |
| Comparative example 3 | Copper powder | AlN | 1.0 | 450 | 50 | 0.26 | 450 |
| Example 1 | Copper powder | AlN | 1.0 | 450 | 55 | 0.26 | 450 |
| Example 2 | Copper powder | AlN | 1.0 | 450 | 60 | 0.26 | 450 |
| Example 3 | Copper powder | AlN | 1.0 | 450 | 65 | 0.26 | 450 |
| Example 4 | Copper powder | AlN | 1.0 | 450 | 70 | 0.26 | 450 |
| Example 5 | Copper powder | AlN | 1.0 | 450 | 75 | 0.26 | 450 |

| | Laser beam | | | | | | | |
|---|---|---|---|---|---|---|---|---|
| | irradiation conditions | | | Coating | | | Average | |
| | Beam 2 | | | material | | | irradiation | Evaluation |
| | | Irradiation | | metal | | | energy | of |
| | Laser | spot | Sweep | supply | Shielding gas | | density E | formation |
| | output | diameter | speed | rate | | Flow rate | [*1] | of metal |
| Example No. | P_{L2} (W) | D_{L2} (mm) | v (mm/s) | (mg/s) | Type | (L/min) | (J/mm²) | layer |
| Comparative example 1 | 40 | 0.26 | 5.0 | 10 | Ar | 10 | 61.5 | C |
| Comparative example 2 | 45 | 0.26 | 5.0 | 10 | Ar | 10 | 69.2 | C |
| Comparative example 3 | 50 | 0.26 | 5.0 | 10 | Ar | 10 | 76.9 | B |
| Example 1 | 55 | 0.26 | 5.0 | 10 | Ar | 10 | 84.6 | A |
| Example 2 | 60 | 0.26 | 5.0 | 10 | Ar | 10 | 92.3 | A |
| Example 3 | 65 | 0.26 | 5.0 | 10 | Ar | 10 | 100.0 | A |
| Example 4 | 70 | 0.26 | 5.0 | 10 | Ar | 10 | 107.7 | A |
| Example 5 | 75 | 0.26 | 5.0 | 10 | Ar | 10 | 115.4 | A |

[*1]: E = (P_{L1}/D_{L1} + P_{L2}/D_{L2})/v

TABLE 2

| | | | | Laser beam irradiation conditions | | | |
|---|---|---|---|---|---|---|---|
| | | | | Beam 1 | | | Beam 2 |
| | Coating | Ceramic plate | | Wavelength | Laser output | Irradiation spot | Wavelength |
| Example No. | material metal | Material | Thickness (mm) | (nm) | P_{L1} (W) | diameter D_{L1} (mm) | (nm) |
| Example 6 | [*2] | Si₃N₄ | 1.0 | 450 | 20 | 0.26 | 450 |
| Example 7 | [*2] | Si₃N₄ | 1.0 | 450 | 25 | 0.26 | 450 |
| Example 8 | [*2] | Si₃N₄ | 1.0 | 450 | 20 | 0.26 | 450 |
| Example 9 | [*2] | Si₃N₄ | 1.0 | 450 | 20 | 0.26 | 450 |
| Example 10 | [*2] | Si₃N₄ | 1.0 | 450 | 20 | 0.26 | 450 |
| Example 11 | [*2] | Si₃N₄ | 1.0 | 450 | 40 | 0.26 | 450 |
| Example 12 | [*2] | Si₃N₄ | 1.0 | 450 | 35 | 0.26 | 450 |
| Example 13 | [*2] | AlN | 1.0 | 450 | 45 | 0.26 | 450 |
| Example 14 | [*2] | AlN | 1.0 | 450 | 55 | 0.26 | 450 |
| Example 15 | [*2] | AlN | 1.0 | 450 | 50 | 0.26 | 450 |
| Example 16 | [*2] | AlN | 1.0 | 450 | 55 | 0.26 | 450 |

| | Laser beam | | | | | | | |
|---|---|---|---|---|---|---|---|---|
| | irradiation conditions | | | Coating | | | Average | |
| | Beam 2 | | | material | | | irradiation | Evaluation |
| | | Irradiation | | metal | Shielding gas | | energy | of |
| | Laser | spot | Sweep | supply | | Flow | density E | formation |
| | output | diameter | speed v | rate | | rate | [*1] | of metal |
| Example No. | P_{L2} (W) | D_{L2} (mm) | (mm/s) | (mg/s) | Type | (L/min) | (J/mm²) | layer |
| Example 6 | 20 | 0.26 | 5.0 | 10 | Ar | 10 | 30.8 | A |
| Example 7 | 25 | 0.26 | 5.0 | 10 | Ar | 10 | 38.5 | A |
| Example 8 | 20 | 0.26 | 5.0 | 5 | Ar | 10 | 30.8 | A |
| Example 9 | 20 | 0.26 | 5.0 | 12.5 | Ar | 10 | 30.8 | A |
| Example 10 | 20 | 0.26 | 5.0 | 15 | Ar | 10 | 30.8 | A |
| Example 11 | 40 | 0.26 | 5.0 | 15 | Ar | 10 | 61.5 | A |
| Example 12 | 35 | 0.26 | 5.0 | 12.5 | Ar | 10 | 53.8 | A |
| Example 13 | 45 | 0.26 | 5.0 | 5 | Ar | 10 | 69.2 | A |
| Example 14 | 55 | 0.26 | 5.0 | 5 | Ar | 10 | 84.6 | A |
| Example 15 | 50 | 0.26 | 5.0 | 10 | Ar | 10 | 76.9 | A |
| Example 16 | 55 | 0.26 | 5.0 | 7.5 | Ar | 10 | 84.6 | A |

[*1]: E = (P_{L1}/D_{L1} + P_{L2}/D_{L2})/v
[*2]: Ag—Cu—Ti alloy powder

FIG. 7 illustrates photographs of the appearance of the ceramic plate after a metal layer production test of each example was performed. The ceramic plate on the left shows the results of Comparative Examples 1, 2, and 3, and Example 1, while the ceramic plate on the right shows the results of Examples 2, 3, 4, and 5. The numerical values (watts) written on the plates are the total laser output (W) of the beams 1 and 2.

### REFERENCE SIGNS LIST

1: ceramic substrate
2: metal layer
10: processing head
20: powder supply device
21: powder supply pipe
22: powder feed nozzle
30a, 30b: laser generator
31a, 31b: optical fiber
200: metal powder
300a, 300b: laser beam
310: irradiation area

1. A method for producing a ceramic-metal bonded object comprising irradiating a surface of a ceramic substrate with a laser beam while sweeping the laser beam, and simultaneously therewith, feeding a solid metal material toward a region irradiated with the laser beam on the surface of the ceramic substrate (hereinafter referred to as “irradiation area”), so that the metal material being fed is also brought into a state of being irradiated with the laser beam to melt the metal material while heating the surface of the ceramic substrate located in the irradiation area, and depositing the molten metal material on the surface of the ceramic substrate and then solidifying the metal material.

2. The method for producing a ceramic-metal bonded object according to claim 1, wherein the solid metal material is a powder.

3. The method for producing a ceramic-metal bonded object according to claim 1, wherein the solid metal material contains any of Cu, Ag, Ti, Ni, Al, Fe, Au, and Pt as a main component.

4. The method for producing a ceramic-metal bonded object according to claim 1, wherein the solid metal material contains Cu or Ag as a main component.

5. The method for producing a ceramic-metal bonded object according to claim 1, wherein one or more laser beams are used, and at least one of the laser beams to be emitted to the metal material being fed has a wavelength of 600 nm or less.

6. The method for producing a ceramic-metal bonded object according to claim 1, wherein one or more laser beams are used, and for at least one of the laser beams to be emitted to the metal material being fed, any of a Yb-doped solid-state laser, a Nd-doped solid-state laser, a GaN semiconductor laser, a copper vapor laser, an Ar gas laser, a N₂ gas laser, and an excimer laser is used as a light source.

7. The method for producing a ceramic-metal bonded object according to claim 1, wherein the solid metal material contains Cu as a main component, and the ceramic substrate contains AlN as a main component.

8. The method for producing a ceramic-metal bonded object according to claim 7, wherein one or more laser beams are used, and the surface of the ceramic substrate is irradiated with the laser beam so that an average irradiation energy density E represented by formula (1) below is 80 to 160 J/mm²:
$$E = ( {P}_{L 1} / {D}_{L 1} + {P}_{L 2} / {D}_{L 2} + … + {P}_{L n} / {D}_{L n} ) / v \qquad ( 1 )$$
wherein
E: an average irradiation energy density E (J/mm²),
sign Li (i=an integer of 1 or more and n or less, n being a total number of laser beams used): an identification sign of each laser beam used,
P_{Li}: a laser output (W) of a laser beam Li,
D_{Li}: an irradiation spot diameter (mm) in a direction perpendicular to a sweep direction of the laser beam Li, and
v: a sweep speed (mm/s) of a laser beam.

9. The method for producing a cerami-metal bonded object according to claim 1, wherein the solid metal material contains Ag as a main component, and the ceramic substrate contains AlN or Si₃N₄ as a main component.

10. The method for producing a ceramic-metal bonded object according to claim 9, wherein one or more laser beams are used, and the surface of the ceramic substrate is irradiated with the laser beam so that an average irradiation energy density E represented by formula (1) below is 25 to 160 J/mm²:
$$E = ( {P}_{L 1} / {D}_{L 1} + {P}_{L 2} / {D}_{L 2} + … + {P}_{L n} / {D}_{L n} ) / v \qquad ( 1 )$$
wherein
E: an average irradiation energy density E (J/mm²),
sign Li (i=an integer of 1 or more and n or less, n being a total number of laser beams used): an identification sign of each laser beam used,
P_{Li}: a laser output (W) of a laser beam Li,
D_{Li}: an irradiation spot diameter (mm) in a direction perpendicular to a sweep direction of the laser beam Li, and
v: a sweep speed (mm/s) of a laser beam.
